(19) United States
(12) Patent Application Publication
(10) Pub. No.: US 2008/0128881 A1
(43) Pub. Date: Jun. 5, 2008

(54) SEMICONDUCTOR DEVICE

(75) Inventor: Tomohisa SEKIGUCHI, Kawasaki (JP)

Correspondence Address: YOUNG & THOMPSON, 209 Madison Street, Suite 500, ALEXANDRIA, VA, 22314, US

(73) Assignee: NEC ELECTRONICS CORPORATION, Kawasaki (JP)

(21) Appl. No.: 11/947,810

(22) Filed: Nov. 30, 2007

(30) Foreign Application Priority Data
Dec. 4, 2006 (JP) 2006-327297

(51) Int. Cl. H01L 23/538

(52) U.S. Cl. 257/686; 257/E23.169

(57) ABSTRACT

In one embodiment, provided is a semiconductor device including a first semiconductor package, a second semiconductor package and a conductive plate. The first semiconductor package includes a first interconnect substrate and a first semiconductor chip. The second semiconductor package includes a second interconnect substrate and a second semiconductor chip, and is stacked on the first semiconductor package. The conductive plate is provided between the first semiconductor package and the second semiconductor package. The conductive plate is electrically coupled to the GND plane of the mounting board, so that a fixed potential is provided. The distance from the lower surface of the first interconnect substrate to the lower surface of the second interconnect substrate is larger than a total of a thickness of the first interconnect substrate, a thickness of the first semiconductor chip and a thickness of the conductive plate.

This application is based on Japanese patent application No. 2006-327,297, the content of which is incorporated hereinto by reference.

### BACKGROUND

1. Technical Field

The present invention relates to a semiconductor device.

2. Related Art

FIG. 9 is a cross-sectional view, showing a conventional semiconductor device. A semiconductor device 100 has a package on package (POP) structure. More specifically, a semiconductor package 120 and a semiconductor package 130 are sequentially stacked on a mounting board 110. A semiconductor package 120 includes an interconnect substrate 122 and a semiconductor chip 124. Similarly, a semiconductor package 130 includes an interconnect substrate 132 and a semiconductor chip 134.

Prior art literatures related to the present invention include

Japanese Patent Laid-Open No. 2000-174,204, Japanese Patent Laid-Open No. 2003-163,310, Japanese Patent Laid-Open No. 2002-271,101, Japanese Patent Laid-Open No. H8-51,127 (1996) and Japanese Patent Laid-Open No. 2005-277,356.

Such structure having the stacked semiconductor packages 120 and 130 in such way provides an increased distance between an interconnect substrate 132 of the semiconductor package 130 located in the upper layer and a ground plane (not shown) of the mounting board 110. Such increased distance causes unstable reference potential, resulting in unstable intrinsic impedance of interconnects in the interconnect substrate 132.

### SUMMARY

According to one aspect of the present invention, there is provided a semiconductor device, comprising: a first semiconductor package including a first interconnect substrate and a first semiconductor chip mounted on the first interconnect substrate, the first semiconductor package being mounted on a mounting board; second semiconductor package including a second interconnect substrate and a second semiconductor chip mounted on the second interconnect substrate, the second semiconductor package being stacked on the first semiconductor package; and an electrically conductive plate provided between the first and the second semiconductor packages, wherein the electrically conductive plate is electrically coupled to a power source plane or a ground plane of the mounting board to be provided with a fixed potential, and wherein a distance from a lower surface of the first interconnect substrate to a lower surface of the second interconnect substrate is larger than a total of a thickness of the first interconnect substrate, a thickness of the first semiconductor chip and a thickness of the electrically conductive plate.

In such aspect of the present invention, the electrically conductive plate having a fixed potential is provided between the first and the second semiconductor packages. This allows providing a stable reference potential, similarly as in a case that a ground plane (or a power source plane) is disposed in vicinity of the interconnect substrate of the second semiconductor package (second interconnect substrate). Thus, a stable intrinsic impedance of the interconnect in the second interconnect substrate can also be provided.

According to the present invention, a semiconductor device having a POP structure, which is suitable for providing a stable intrinsic impedance of an interconnect in an interconnect substrate that is included in an upper semiconductor package, is achieved.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view, illustrating first embodiment of a semiconductor device according to the present invention;

FIG. 2 is a cross-sectional view, useful in describing an advantageous effect of the embodiment;

FIG. 3 is a cross-sectional view, illustrating second embodiment of a semiconductor device according to the present invention;

FIG. 4 is a cross-sectional view, illustrating third embodiment of a semiconductor device according to the present invention;

FIG. 5 is a cross-sectional view, illustrating a modified embodiment according to the present invention;

FIG. 6 is a cross-sectional view, illustrating another modified embodiment according to the present invention;

FIG. 7 is a cross-sectional view, illustrating a further modified embodiment according to the present invention;

FIG. 8 is a cross-sectional view, illustrating a yet other modified embodiment according to the present invention; and

FIG. 9 is a cross-sectional view, illustrating a conventional semiconductor device.

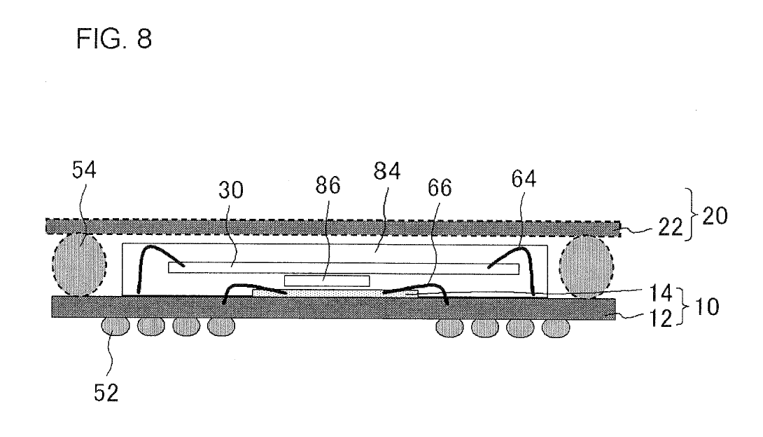

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Preferable exemplary implementations of semiconductor devices according to the present invention will be described in reference to the annexed figures. In all figures, an identical numeral is assigned to an element commonly appeared in the description of the present invention in reference to the figures, and the detailed description thereof will not be repeated.

### FIRST EMBODIMENT

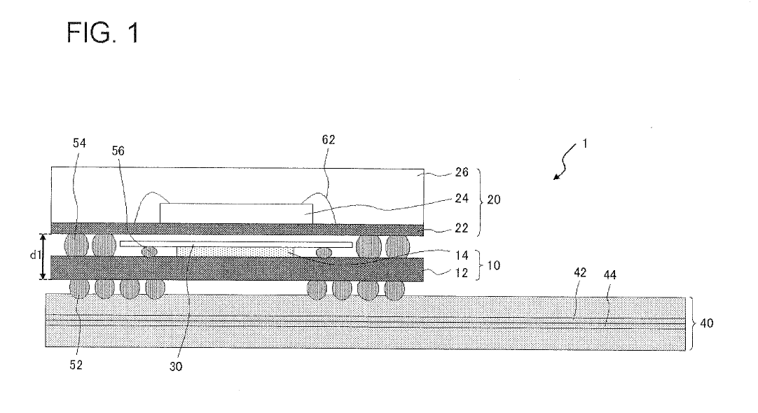

FIG. 1 is a cross-sectional view showing the first embodiment of a semiconductor device by the present invention. A semiconductor device 1 includes a semiconductor package 10 (first semiconductor package), a semiconductor package 20 (second semiconductor package) and an electrically conductive plate 30. The semiconductor package 10 includes an interconnect substrate 12 (first interconnect substrate) and a semiconductor chip 14 (first semiconductor chip). The interconnect substrate 12 is substantially flat. The semiconductor chip 14 is mounted on the interconnect substrate 12 by a flip-chip bonding. The semiconductor package 10 is mounted on a mounting board 40 via conductive bumps 52. The mounting board 40 includes a ground (hereinafter referred to as “GND”) plane 42 and a power source plane 44. In addition to above, the GND plane 42 is electrically isolated from the power source plane 44 by an insulating layer that is not shown.

The semiconductor package 20 is disposed on the semiconductor package 10. The semiconductor package 20 includes an interconnect substrate 22 (second interconnect substrate) and a semiconductor chip 24 (second semiconductor chip). The interconnect substrate 22 is located as being spaced apart from the interconnect substrate 12. Neither a power source plane nor a GND plane is provided in such interconnect substrate 22. The semiconductor chip 24 is operatively mounted on the interconnect substrate 22 by a wire bonding. More specifically, the interconnect substrate 22 is electrically coupled to the semiconductor chip 24 by bonding wires 62. Further, an encapsulating resin 26 is formed on the interconnect substrate 22 so as to cover the semiconductor chip 24. This semiconductor package 20 is mounted on the semiconductor package 10 via conductive bumps 54 therebetween. In addition to above, the above-described semiconductor chip 24 and the semiconductor chip 14 are, for example, a memory chip and a controller chip, respectively.

The electrically conductive plate 30 is provided between the semiconductor package 10 and the semiconductor package 20. The electrically conductive plate 30 is spaced apart from the interconnect substrate 22, and is not fixed to the interconnect substrate 22. Such conductive plate 30 is coupled to the interconnect substrate 12 through conductive bumps 56. While the conductive plate 30 is disposed on a back surface of the semiconductor chip 14 (that is, surface in a side opposite to a circuit-formed surface (first surface); second surface) since the semiconductor chip 14 is mounted in a face-down orientation in the present embodiment, the conductive plate 30 may be configured to be fixed on the back surface thereof, or may not be configured to be fixed thereto. In the former configuration, the conductive plate 30 is adhered on the back surface of the semiconductor chip 14 with an insulating paste material, for example. In addition to above, a material for such conductive plate 30 may be copper, for example. Further, a material for each of the conductive bumps 52, 54 and 56 may be solder, for example.

The conductive plate 30 is electrically coupled to the GND plane 42 of the mounting board 40, so that a fixed potential (GND potential in the present embodiment) is provided. More specifically, the conductive plate 30 is electrically coupled to the GND plane 42 via the conductive bumps 56, an interconnect (not shown) in the interconnect substrate 12, the conductive bumps 52 and an interconnect (not shown) in the mounting board 40.

In the semiconductor device 1, as can be seen in FIG. 1, a distance d1 from the lower surface of the interconnect substrate 12 to the lower surface of the interconnect substrate 22 is larger than a total of a thickness of the interconnect substrate 12, a thickness of the semiconductor chip 14 and a thickness of the conductive plate 30. In addition to above, when the thickness of the interconnect substrate is not even, the thickness of the interconnect substrate is defined as the maximum thickness in the interconnect substrate.

Advantageous effects obtainable by employing the configuration of the present embodiment will be described. In the present embodiment, the electrically conductive plate 30 having a fixed potential is provided between the first semiconductor package 10 and the second semiconductor package 20. This allows providing a stable reference potential, similarly as in a case that the GND plane (or a power source plane) is disposed in vicinity of the interconnect 22 substrate of the semiconductor package 20 in the upper layer. Thus, a stable intrinsic impedance of the interconnect in the interconnect substrate 22 can also be provided.

More detailed discussion will be made on such advantageous effect. An intrinsic impedance Z₀ is represented by:

Z₀÷(L/C)½.

Thus, changes in an inductance (L) or a capacitance (C) per cross section of the interconnect would cause a change in Z₀, possibly causing a reflection. Longer distance between the interconnect and the GND plane would provide greater tendency of changing values of L and C, increasing the instability of Z₀. On the contrary, since the conductive plate 30 disposed near the interconnect substrate 22 functions as a GND plane in the semiconductor device 1 even if the distance between the interconnect substrate 22 and the GND plane 42 in the mounting board 40 is longer, variations in L and C can be reduced. As a result, Z₀ of the interconnect in the interconnect substrate 22 is stabilized.

Further, in the present embodiment, the distance d1 from the lower surface of the interconnect substrate 12 to the lower surface of the interconnect substrate 22 is larger than a total of a thickness of the interconnect substrate 12, a thickness of the semiconductor chip 14 and a thickness of the conductive plate 30. Such configuration can be achieved by employing a flat interconnect substrate for the interconnect substrate 12. Actually, the interconnect substrate 12 is substantially flat, as described above. Such flat interconnect substrate can be easily manufactured. This leads to a reduction in manufacturing costs for the semiconductor device 1.

However, while the above-described configuration exhibits the above described benefits, the configuration also exhibits a disadvantage of considerably causing the above-described problems related to the intrinsic impedance. More specifically, since the longer dimension of the above-described distance d1 provides a larger distance from the interconnect substrate 22 to the GND plane 42 in the mounting board 40, an absence of a conductive plate 30 would cause a considerably unstable intrinsic impedance of the interconnect in the interconnect substrate 22. Hence, a presence of the conductive plate 30 in the above-described configuration is particularly helpful.

On the contrary, Japanese Patent Laid-Open No. 2000-174,204 discloses a semiconductor device, in which a concave portion is formed in a surface of an interconnect substrate and a semiconductor chip is installed in the concave portion. Another interconnect substrate is stacked on the above-described interconnect substrate. The above-described structure provides a configuration in such semiconductor device, in which a distance between the lower surfaces of both interconnect substrates is smaller than a total of the thickness of the interconnect substrate located in the lower side and the thickness of the above-described semiconductor chip. However, more complicated manufacturing processes for such type of interconnect substrate having concave portions formed therein are generally required, as compared with the process for flat substrates.

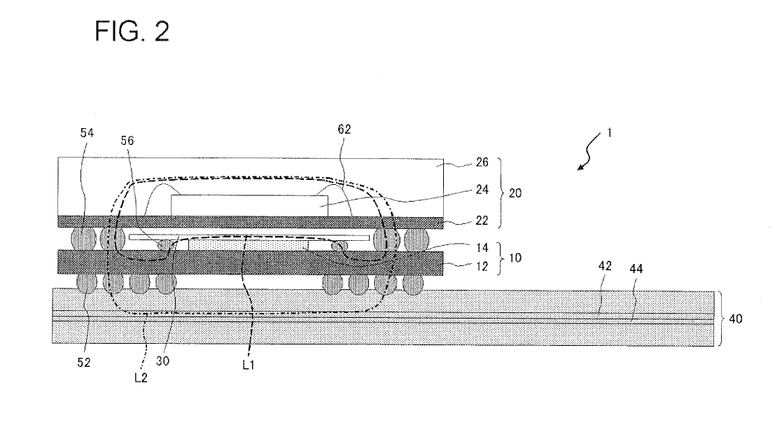

Further, according to the present embodiment, as shown in FIG. 2, a dimension of a loop of electric current passing through the semiconductor package 20 (loop indicated by dotted line L1) is decreased to be smaller than a loop of electric current passing through the semiconductor package 20 without having a conductive plate 30 (loop indicated by alternate-long-and-short dash line L2). This allows reducing an impedance in the electric current loop.

The conductive plate 30 also functions as an electromagnetic shield. Thus, even if the interconnect substrate 12 emits an electromagnetic noise, such noise can be removed by the presence of the conductive plate 30. This allows preventing the characteristics of the semiconductor chip 24 from being affected by the electromagnetic noise. Further, the conductive plate 30 also functions as a heat sink. Thus, a heat generated in the interconnect substrate 12 can be dissipated by the conductive plate 30 with an improved efficiency. This allows reducing influences of the above-described heat over the interconnect substrate 22 or the semiconductor chip 24.

Neither a power source plane nor a GND plane is provided in the interconnect substrate 22. This is advantageous in achieving a miniaturization of the semiconductor package 20 (in particular reduction of package thickness).

The conductive plate 30 is disposed to be spaced apart from the interconnect substrate 22. This allows providing an increased design flexibility for the distance between the interconnect substrate 22 and the conductive plate 30. More specifically, a height of the conductive bump 56 is adjusted to allow the conductive plate 30 to be disposed in a desired position between the semiconductor chip 14 and the interconnect substrate 22.

When the conductive plate 30 is not fixed to the semiconductor chip 14 or to the interconnect substrate 22, the above-described design flexibility is still further enhanced. This is because the position of the conductive plate 30 can be determined by using only the height of the conductive bump 56.

### SECOND EMBODIMENT

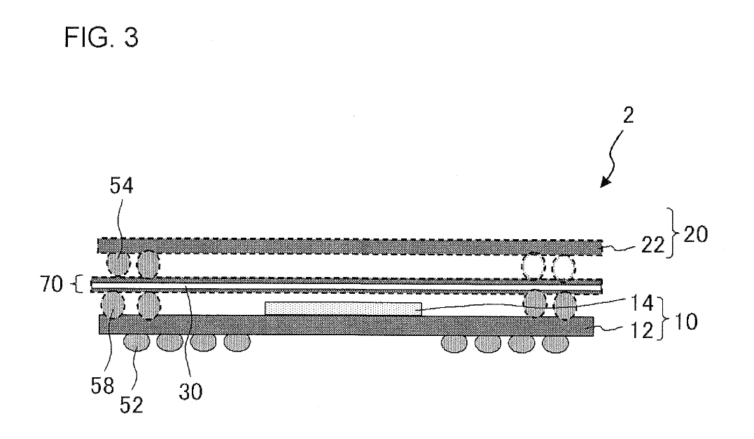

FIG. 3 is a cross-sectional view, illustrating second embodiment of a semiconductor device according to the present invention. A semiconductor device 2 includes a holding substrate 70, which is capable of holding the conductive plate 30, in addition to the semiconductor packages 10 and 20 and the conductive plate 30. The holding substrate 70 is coupled to the interconnect substrate 12 via conductive bumps 58. The semiconductor package 20 is, in turn, mounted on the holding substrate 70 via conductive bumps 54. This provides a configuration, in which the semiconductor package 10 is coupled to the semiconductor package 20 via the holding substrate 70. Other configurations of the semiconductor device 2 are similar to that of the semiconductor device 1 shown in FIG. 1. However, an illustrations of the semiconductor chip 24, the mounting board 40 or the like (see FIG. 1) is not presented in FIG. 3.

According to the semiconductor device 2 having such configuration, a larger dimension of the conductive plate 30 can be obtained. The conductive plate 30 having a dimension that is enough to fit between the conductive bumps 54 is required to be employed in an absence of the holding substrate 70 as shown in FIG. 1, since a presence of the holding substrate 70 prevents such limitation. In the semiconductor device 2, the conductive plate 30 having a dimension that is substantially the same as that of the interconnect substrates 12 and 22 is employed. Other advantageous effects of semiconductor device 2 is similar to that of the semiconductor device 1.

### THIRD EMBODIMENT

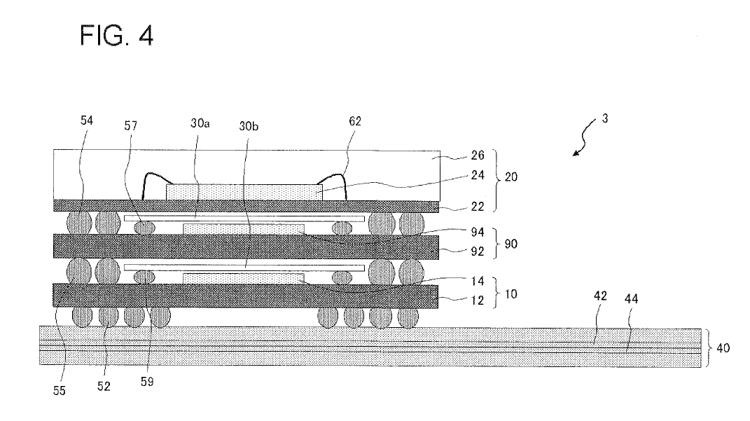

FIG. 4 is a cross-sectional view, illustrating third embodiment of a semiconductor device according to the present invention. In a semiconductor device 3, three semiconductor packages are stacked on a mounting board 40. More specifically, a semiconductor package 90 having an interconnect substrate 92 and a semiconductor chip 94 interposes between the semiconductor package 10 and the semiconductor package 20. The semiconductor package 90 is mounted on the semiconductor package 10 via conductive bumps 55. The semiconductor package 20 is, in turn, mounted on the semiconductor package 90 via the conductive bumps 54. Conductive plates 30a and 30b are provided between the semiconductor package 10 and the semiconductor package 20. More specifically, the conductive plate 30a is provided between the semiconductor package 20 and the semiconductor package 90, and the conductive plate 30b is provided between the semiconductor package 90 and the semiconductor package 10. The conductive plate 30a is coupled to the interconnect substrate 92 via conductive bumps 57. Similarly, the conductive plate 30b is coupled to the interconnect substrate 12 via conductive bumps 59. Other configurations of the semiconductor device 3 are similar to that of the semiconductor device 1 shown in FIG. 1.

The configuration including three semiconductor packages stacked in such manner can achieve more sophisticated semiconductor device 3. Further, the presence of the conductive plates 30a and 30b provides a stabilized intrinsic impedance in the interconnect in the interconnect substrate 22 and in the interconnect in the interconnect substrate 92. However, it is not essential to provide both conductive plates 30a and 30b, and it is sufficient to have either one of the conductive plates. Other advantageous effects of the semiconductor device 3 are similar to that of the semiconductor device 1 shown in FIG. 1.

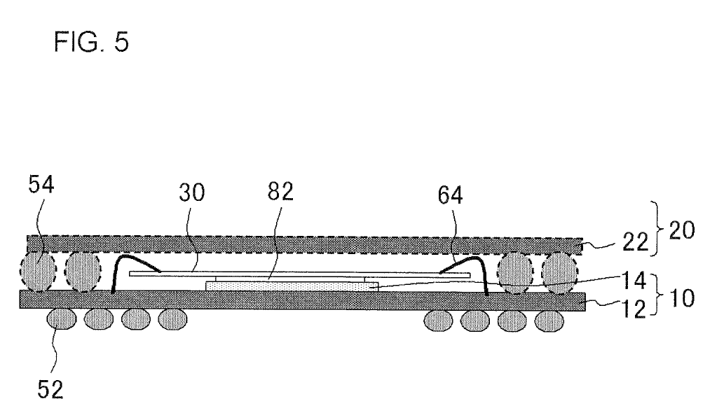

It is not intended to limit the scope of the present invention to the above-described exemplary implementations of the semiconductor devices according to the present invention, and various modifications other than that disclosed above may also be available. While the above-described embodiments illustrates the configuration that the conductive plate 30 is coupled to the interconnect substrate 12 via the conductive bumps, the conductive plate 30 may alternatively be coupled to the interconnect substrate 12 via bonding wires 64 as shown in FIG. 5. In FIG. 5, the conductive plate 30 is adhered onto a back surface of the semiconductor chip 14 with an insulating paste material 82. In this case, it is preferable to form a plated film such as silver plated film and the like on the conductive plate 30 for the purpose of providing a coupling with the bonding wire 64.

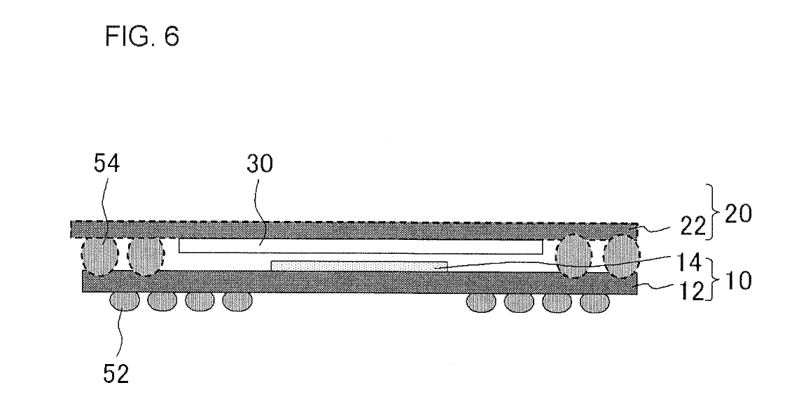

While the example of the conductive plate 30 spaced apart from the interconnect substrate 22 is illustrated in the above-described embodiments, the conductive plate 30 may alternatively be adhered onto the interconnect substrate 22 as shown in FIG. 6. In this case, the conductive plate 30 is electrically coupled to a GND plane in a mounting board via the interconnects in the interconnect substrate 22, the conductive bumps 54, the interconnects in the interconnect substrate 12, the conductive bumps, and the like.

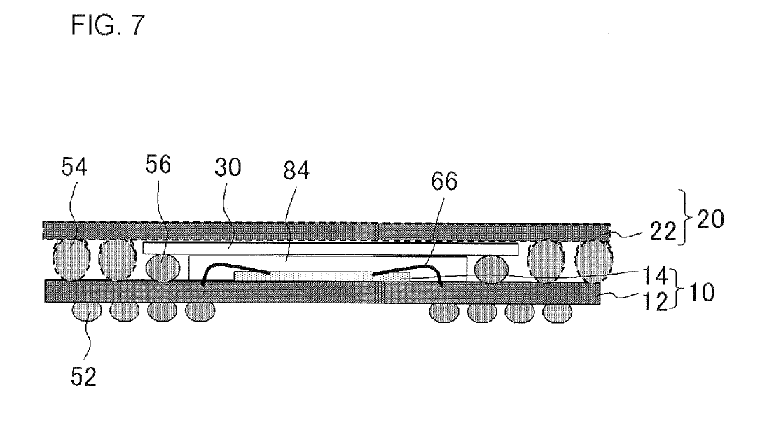

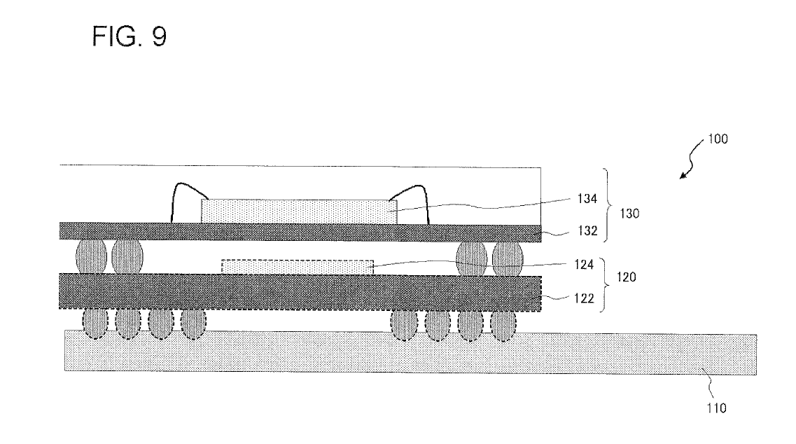

While the example of the semiconductor chip 14 flip-chip mounted on the interconnect substrate 12 is illustrated in the above-described embodiments, the semiconductor chip 14 may alternatively be mounted on the interconnect substrate 12 by wire bondings as shown in FIG. 7 and FIG. 8. FIG. 7 and FIG. 8 illustrate that the semiconductor chip 14 is electrically coupled to the interconnect substrate 12 via bonding wires 66. Further, an encapsulating resin 84 is formed on the interconnect substrate 12 so as to cover the semiconductor chip 14. FIG. 7 illustrates that the conductive plate 30 is adhered onto the encapsulating resin 84 and is coupled to the interconnect substrate 12 via the conductive bumps 56. On the other hand, FIG. 8 illustrates that the conductive plate 30 is coupled to the interconnect substrate 12 via the bonding wires 64 and is buried in the encapsulating resin 84. Further, a spacer 86 interposes between the semiconductor chip 14 and the conductive plate 30. In addition to above, an illustration of the semiconductor chip 24, the mounting board 40 or the like (see FIG. 1) is not presented in FIG. 7 and FIG. 8, similarly as in FIG. 3.

While the example of the conductive plate 30 electrically coupled to the GND plane 42 is illustrated in the above-described embodiments, the conductive plate 30 may alternatively be electrically coupled to the power source plane 44. In addition to above, if a plurality of power source planes 44 are provided in the mounting board 40, it is sufficient that the conductive plate 30 is electrically coupled to either one of the power source planes 44. Further, the fixed potential of the conductive plate 30 is not required to be equivalent to a power source potential of the power source plane 44 that is electrically coupled to the conductive plate 30. For example, a voltage drop along a path from the power source plane 44 to the conductive plate 30 may reduce the above-described fixed potential to be lower than a power source potential of the power source plane 44.

While the example of the semiconductor device in the condition of being mounted on the mounting board 40 is illustrated in the above-described embodiments, the semiconductor device according to the present invention may be in the condition of not being mounted on the mounting board 40.

While the example of two or three stacked semiconductor packages is illustrated in the above-described embodiments, four or more stacked semiconductor packages may alternatively be employed.

It is apparent that the present invention is not limited to the above embodiment, and may be modified and changed without departing from the scope and spirit of the invention.

What is claimed is:

1. A semiconductor device, comprising:
a first semiconductor package including a first interconnect substrate and a first semiconductor chip mounted on said first interconnect substrate, said first semiconductor package being mounted on a mounting board;
a second semiconductor package including a second interconnect substrate and a second semiconductor chip mounted on said second interconnect substrate, said second semiconductor package being stacked on said first semiconductor package; and
an electrically conductive plate provided between said first and said second semiconductor packages,
wherein said electrically conductive plate is electrically coupled to a power source plane or a ground plane of said mounting board to be provided with a fixed potential, and
wherein a distance from a lower surface of said first interconnect substrate to a lower surface of said second interconnect substrate is larger than a total of a thickness of said first interconnect substrate, a thickness of said first semiconductor chip and a thickness of said electrically conductive plate.

2. The semiconductor device as set forth in claim 1, wherein
said first interconnect substrate is substantially flat.

3. The semiconductor device as set forth in claim 1, wherein neither a power source plane nor a ground plane is provided in said second interconnect substrate.

4. The semiconductor device as set forth in claim 1, wherein said first interconnect substrate is spaced apart from said second interconnect substrate.

5. The semiconductor device as set forth in claim 1, wherein said electrically conductive plate is spaced apart from said second interconnect substrate.

6. The semiconductor device as set forth in claim 1, wherein said conductive plate is coupled to said first interconnect substrate via a conductive bump.

7. The semiconductor device as set forth in claim 6, wherein said electrically conductive plate is not fixed on said first semiconductor chip, neither fixed on said second interconnect substrate.

8. The semiconductor device as set forth in claim 1, wherein said electrically conductive plate is coupled to said first interconnect substrate via a bonding wire.

9. The semiconductor device as set forth in claim 1, wherein said electrically conductive plate is adhered to said second interconnect substrate.

10. The semiconductor device as set forth in claim 1, further comprising a holding substrate that is capable of holding said electrically conductive plate, wherein said first semiconductor package is coupled to said second semiconductor package via said holding substrate.

11. The semiconductor device as set forth in claim 1, wherein said first semiconductor chip is mounted on said first interconnect substrate through a flip chip bonding.

12. The semiconductor device as set forth in claim 11, wherein said first semiconductor chip has opposite first and second surfaces, said first surface facing to said first interconnect substrate, and wherein said electrically conductive plate is adhered to said second surface of said first semiconductor chip.

13. The semiconductor device as set forth in claim 1, wherein said first semiconductor chip is electrically coupled to said first interconnect substrate by a bonding wire, and is covered with an encapsulating resin.

14. The semiconductor device as set forth in claim 13, wherein said electrically conductive plate is adhered onto said encapsulating resin.

15. The semiconductor device as set forth in claim 13, wherein said electrically conductive plate is buried within said encapsulating resin.
